(19) United States
(12) Patent Application Publication
(10) Pub. No.: US 2021/0223697 A1
(43) Pub. Date: Jul. 22, 2021

(54) CYLINDRICAL SEMICONDUCTOR INTEGRATED CIRCUITS AND CONCENTRIC PHOTOLITHOGRAPHY FOR THE FABRICATION THEREOF

(71) Applicant: SHAHZAD AKBAR, SOUTH CHESTERFIELD, VA (US)

(72) Inventor: SHAHZAD AKBAR, SOUTH CHESTERFIELD, VA (US)

(21) Appl. No.: 16/690,096

(22) Filed: Nov. 20, 2019

Related U.S. Application Data
(60) Provisional application No. 62/777,122, filed on Dec. 8, 2018.

(51) Int. Cl. G03F 7/24; G03F 7/20; G03F 9/00

(52) U.S. Cl. CPC G03F 7/24; G03F 9/7003; G03F 7/703

(57) ABSTRACT

An integrated circuit comprises a silicon cylinder having a sidewall upon which a plurality of semiconductor devices have been printed, one or more electrical leads electrically connected to each semiconductor device, and a plurality of radial wiring interconnects projecting outward from the sidewall.

### CROSS-REFERENCE TO RELATED APPLICATIONS

This application claims priority to pending U.S. Provisional Application Ser. No. 62/777,122, filed Dec. 8, 2018, the contents of which are incorporated herein by reference in its entirety.

### FIELD OF THE INVENTION

This invention relates to integrated circuits comprised of semiconductor devices such as transistors, diodes, resistors, capacitors, inductors, lasers and the like that form the basis of modern electronics.

### BACKGROUND

In conventional silicon chip manufacturing, a planar silicon wafer is coated with a photoresist. The desired semiconductor patterns are produced on a planar photomask. Light is beamed at the photomask such that the pattern is projected onto the photoresist layer. This pattern hardens into an exact representation of the photomask when it is developed. Etching then removes selective areas of the pattern using a plasma that reacts to the material not covered by the hardened photoresist.

The limited space on the planar surface of the silicon wafer limits the number of circuits that can be created on the planar surface.

### BRIEF SUMMARY OF THE DISCLOSURE

An integrated circuit comprises a silicon cylinder having a sidewall upon which a plurality of semiconductor devices have been printed, one or more electrical leads electrically connected to each semiconductor device, and a plurality of radial wiring interconnects projecting outward from the sidewall.

At least some of the electrical leads may terminate at a bottom edge of the sidewall.

One or more of the electrical leads may terminate at a corresponding one of the radial wiring interconnects, enabling three dimensional integration.

Alternative embodiments of the invention comprise a method of manufacturing an integrated circuit. The method comprises printing a plurality of semiconductor devices on a sidewall of a silicon cylinder and slicing the silicon cylinder into a plurality of thinner silicon cylinders. Each thinner silicon cylinder has a plurality of semiconductor devices printed on its sidewall.

Printing a plurality of semiconductor devices on a sidewall of a silicon cylinder may comprise placing a concentric photomask in a position surrounding at least a portion of the silicon cylinder and projecting light from outside the concentric photomask radially inward toward the silicon cylinder.

Printing a plurality of semiconductor devices on a sidewall of a silicon cylinder may comprise projecting light through a planar photomask toward the silicon cylinder and rotating the silicon cylinder to enable the light to sequentially strike different portions of the silicon cylinder.

### BRIEF DESCRIPTION OF THE SEVERAL VIEWS OF THE DRAWINGS

Reference will now be made to the accompanying drawings, which are not necessarily drawn to scale. The following detailed description of the disclosure will be better understood when read in conjunction with the appended drawings. It should be understood, however, that the disclosure is not limited to the precise arrangements and instrumentalities shown. In the drawings:

FIG. 1 illustrates a plurality of integrated circuits, comprising a plurality of semiconductor devices, printed on the sidewall of a silicon cylinder, in accordance with embodiments of the invention.

FIG. 2 illustrates one of the integrated circuits of FIG. 1 sliced from the silicon cylinder (which is termed herein a “cylindrical integrated circuit or cylindrical chip”).

FIG. 3 illustrates a concentric optical photolithography camera using cylindrical curved photomask that focuses the circuit pattern using the radially impinging ultra-violet light on the photoresist coated surface of a silicon cylinder, in accordance with embodiments of the invention.

FIG. 4 illustrates a cylindrical chip of embodiments of the invention packaged in a conventional surface mount package for attachment to a conventional printed circuit board.

FIG. 5 illustrates a cylindrical chip of embodiments of the invention packaged with an antenna to form an RFID tag.

FIG. 6 illustrates a concentric optical photolithography camera using a planar photomask and refractive step-and-repeat optics to print the circuit pattern on the curved side of the silicon cylinder, in accordance with embodiments of the invention.

FIG. 7 illustrates a concentric optical photolithography camera using a planar photomask and reflective optics to print the circuit pattern on the curved side of the silicon cylinder, in accordance with embodiments of the invention.

FIG. 8 illustrates a light emitting diode (LED) device and a solar cell using a cylindrical chip of embodiments of the invention.

### DETAILED DESCRIPTION OF THE DISCLOSURE

Certain terminology is used in the following description for convenience only and is not limiting. The words “lower,” “bottom,” “upper,” “top,” “left” and “right” and the like designate directions in the drawings to which reference is made. The words “inwardly,” “outwardly,” “upwardly” and “downwardly” and the like refer to directions toward and away from, respectively, the geometric center of the device, and designated parts thereof, in accordance with the present disclosure. Unless specifically set forth herein, the terms “a,” “an” and “the” are not limited to one element, but instead should be read as meaning “at least one.” The terminology includes the words noted above, derivatives thereof and words of similar import.

Embodiments of the invention are directed to cylindrical integrated circuits (ICs), devices and methods for making cylindrical integrated circuits, and electronic devices containing such cylindrical integrated circuits. Such cylindrical ICs comprise a plurality of semiconductor devices (primarily transistors) printed on the curved sidewall of a cylindrical silicon ingot (rather than on flat silicon wafers, as with conventional ICs).

Instead of printing the layers of photomask patterns on a flat planar wafer, embodiments of the invention print the circuits on the side of a semiconductor cylinder typically grown as an ingot from the melt, such as by using Czochralski crystal pullers or any other suitable method. The electronic components are fabricated on the sidewall of the ingot, using one or more of the methods described herein or any other suitable method. Once the fabrication is completed, the cylinder is sliced or sawed into thin cylindrical discs with the integrated circuits printed on the sides. The wiring can then be connected as needed with other cylindrical integrated circuits to form three dimensional networks. Since the top flat surface of the cylinder is comprised of single crystal silicon, active devices and circuits can be integrated with other discs. The cylindrical integrated circuits may also be packaged in conventional surface mount and dual inline packages to replace planar ICs.

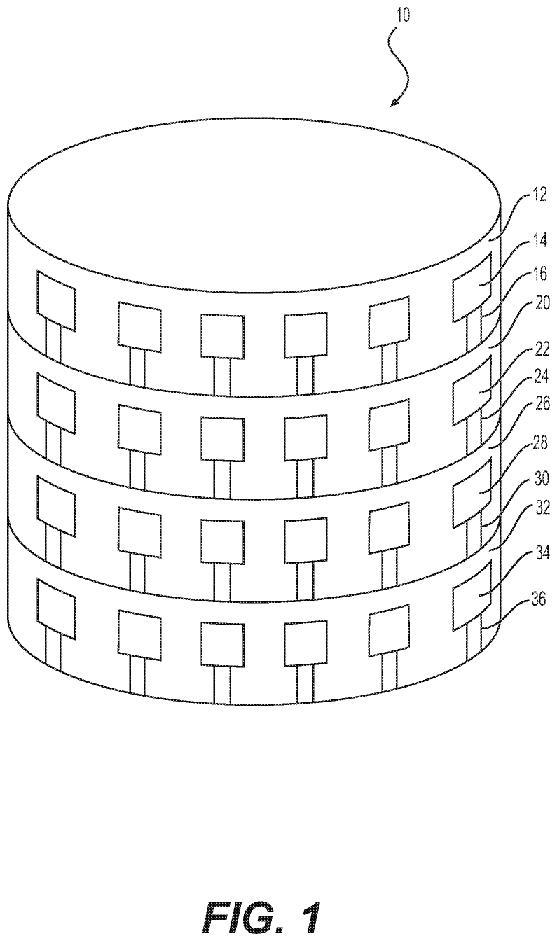

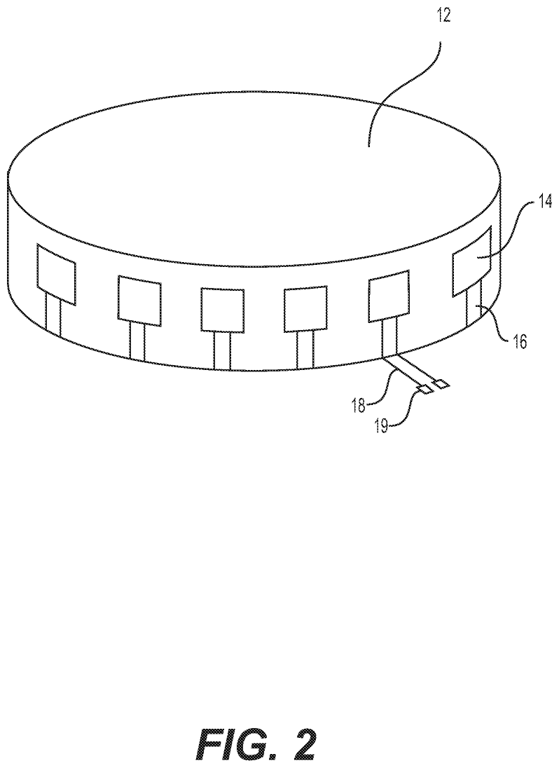

Referring now to the figures, FIG. 1 illustrates a plurality of cylindrical integrated circuits printed on the sidewall of a cylindrical silicon ingot 10, in accordance with embodiments of the invention. The cylindrical silicon ingot 10 is similar to an ingot from which silicon wafers are sliced for conventional silicon chip manufacturing, but typically with a much smaller diameter. In a process described further below, the cylindrical ICs 12, 20, 26, 32 are printed on the sidewall of the cylindrical silicon ingot 10 in adjacent bands. The ingot 10 is then sliced between each cylindrical IC to separate the cylindrical ICs. One of the separate cylindrical ICs 12 is illustrated in FIG. 2. The slicing technique is similar to that for conventional silicon chip manufacturing, but the resulting slices may have a greater thickness to provide space on the sidewall for the semiconductor devices.

Each cylindrical IC comprises a plurality of semiconductor devices (primarily, but not necessarily only, transistors and diodes) with corresponding conductive lead wires. In FIG. 1, cylindrical IC 12 comprises semiconductor devices 14 with leads 16, cylindrical IC 20 comprises semiconductor devices 22 with leads 24, cylindrical IC 26 comprises semiconductor devices 28 with leads 30, and cylindrical IC 32 comprises semiconductor devices 34 with leads 36. (For simplicity, the semiconductor devices 14, 22, 28, 34 are illustrated simply as boxes and are not to scale.) The leads terminate at or near the bottom edge of the cylindrical IC such that each lead may be electrically connected to a corresponding lead or pad connected to wires in a dual in line package (DIP) or SMT surface mount technology (SMT) package that may subsequently be connected to multilayer wiring on a printed circuit board (PCB) (or other substrate). The cylindrical IC may also be secured directly by soldering or by insertion into a suitably designed hole in a dielectric or semiconductor substrate. The substrates may be flexible and may be vertically connected, thereby enabling three-dimensional integration.

While FIGS. 1 and 2 illustrate all of the semiconductor devices 14, 22, 28, 34 located at a same level around the sidewall of each respective cylindrical IC, cylindrical ICs of embodiments of the invention may have semiconductor devices that are located at varying levels and positions around the sidewall. Also, cylindrical ICs of embodiments of the invention would likely have a much greater number and density of semiconductor devices on the sidewall.

In one exemplary embodiment, a cylindrical IC of embodiments of the invention may have a diameter of about 20 millimeters and a height of about 5 millimeters, and may comprise numerous semiconductor devices on its sidewall.

As illustrated in FIG. 2, cylindrical ICs of embodiments of the invention may have radial wiring interconnects 18 terminating in pads 19 protruding from the sidewall or mating with pads fabricated on the inside of holes in substrates which may be connected outwards to other cylindrical ICs to form three-dimensional networks. Such radial wiring interconnects may connect to the conductive leads 16, 24, 30, 36 and/or may connect directly to the semiconductor devices 14, 22, 28, 34. Cylindrical ICs of embodiments of the invention enable systems integrating logic with memory to be easily and beneficially fabricated. The radial wiring interconnects may be formed on separate insulating sheets using conventional multilevel metallization comprising of thin film metal deposition, photolithographic patterning, reactive ion etching followed by insulating layers deposition and etching to form desired wiring interconnects. Precise holes may be cut to insert the cylindrical semiconductor circuits to make electrical contacts. The three dimensional integration would allow advanced performance, speed and system architecture advantages for this invention.

In conventional silicon chip manufacturing, a planar silicon wafer is coated with a photoresist. The desired semiconductor patterns are produced on a planar photomask. Light is beamed at the photomask such that the pattern is projected onto the photoresist layer. This pattern hardens into an exact representation of the photomask when it is developed. Etching then removes selective areas of the pattern using a plasma that reacts to the material not covered by the hardened photoresist.

Embodiments of the invention print the semiconductors on the silicon cylinder sidewall using sequential semiconductor processing techniques similar to that of conventional silicon chip production. However, in preferred embodiments of the invention, the circuit patterns are printed on the sidewall of the silicon cylinder by a concentric optical photolithography camera. The light beams are radially impingent on the photoresist coated surface through a cylindrical concentric photomask. The concentric photomask may be constructed out of thin curved glass or quartz, or any other suitable material. This technique may be termed concentric photolithography. After exposure, the photoresist is conventionally developed to transfer the pattern on to the cylindrical surface. Direct writing electron beam lithography may also be deployed without the need for photomasks.

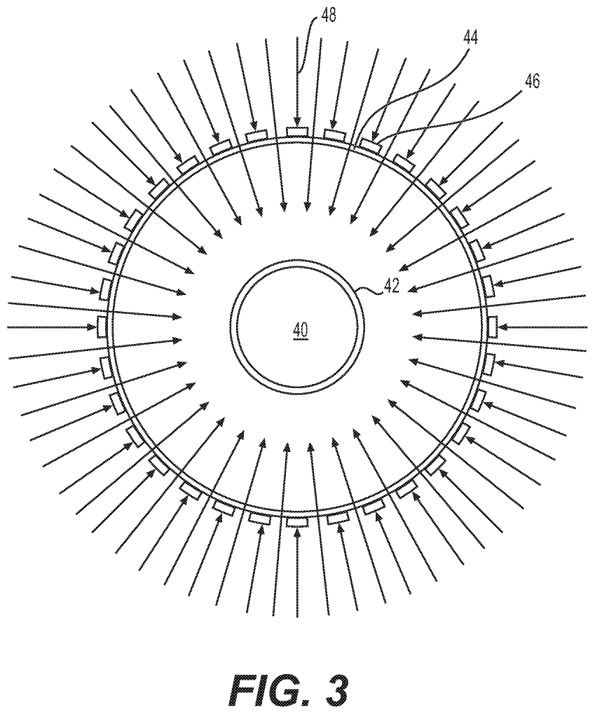

Referring now to FIG. 3, the concentric photolithography of embodiments of the invention is illustrated. The silicon cylinder 40 is coated with photoresist 42. A concentric photomask surrounds the silicon cylinder 40, the concentric photomask comprising a substrate 44 upon which a pattern 46 of the desired circuitry has been created. One or more light sources surround the photomask to beam light 48 radially inward toward the photomask. As seen in FIG. 3, some of the light is blocked by the pattern 46 and some of the light passes through the substrate 44 to reach the photoresist 42.

Advantageously, the concentric geometry allows reduction of the image in the radial focal plane. In other words, the circuit pattern produced on the silicon cylinder is smaller/finer than the pattern on the photomask. Due to current limits in the ability to produce smaller/finer photomasks, this advantage may enable the production of smaller/finer circuitry on the silicon cylinder than is currently able to be produced using conventional photolithography. Systems and methods of concentric photolithography of embodiments of the invention provide improved performance and reduced fabrication cost and less-stringent contamination requirements than conventional photolithography.

The one or more light sources that create the light 48 may comprise any suitable type, number, and arrangement of light sources. Generally, whatever light sources are used for conventional planar photolithography should also work for the concentric photolithography of embodiments of the present invention, except that concentric photolithography requires 360 degrees of light around the photomask (except in embodiments in which the cylinder is rotated, as in the alternative embodiments described below).

Traditionally, the light sources have been mercury gas discharge lamps that were used to extract single wavelengths of 436 nanometers (nm) (“g-line”), 405 nm (“h-line”), and 365 nm (“i-line”) for printing lines larger than 0.5 micrometers. Argon fluoride (ArF) 193 nm excimer laser sources have been used to bring the resolution down to 45 nm. Extreme UV (EUV) light (13.5 nm) sources are being used for state of the art 10 nm lithography. Again, these light sources that are used for conventional planar photolithography should also work for the concentric photolithography of embodiments of the present invention.

For cylindrical sidewall printing, one exemplary embodiment may use a ring of many (e.g., 50) Ultra-Violet Light Emitting Diodes (UV LEDs) concentric with the circular photomask. The LED ring diameter and the diode spacing would depend upon the light intensity, the depth of focus, and other factors. The diameter of the light source ring may be, for example, ten times the diameter of the silicon cylinder.

Rather than spacing a larger number of light sources around the photomask, alternative embodiments might use a smaller number of light sources with properly arranged mirrors to provide the desired 360 degrees of light (in this regard, the lights and mirrors together may be considered lights sources).

The cylindrical photomask may be constructed of any suitable curved and/or flexible glass, such as Corning™ Willow™ glass (which is desirably transparent in the g- h- and i-line wavelengths).

Systems and methods of concentric photolithography of embodiments of the invention may use ultra-violet radiation, extreme ultra-violet radiation (EUV), electron beams, x-rays, or any other form of radiation or particles.

Systems and methods of concentric photolithography of embodiments of the invention may use any suitable conventional techniques of semiconductor manufacturing, such as oxidation, diffusion, photolithography, etching, chemical vapor and physical deposition, planarization, ion implantation and metallization, etc., except that the circuit is printed on the sidewalls of a cylinder instead of on a planar wafer.

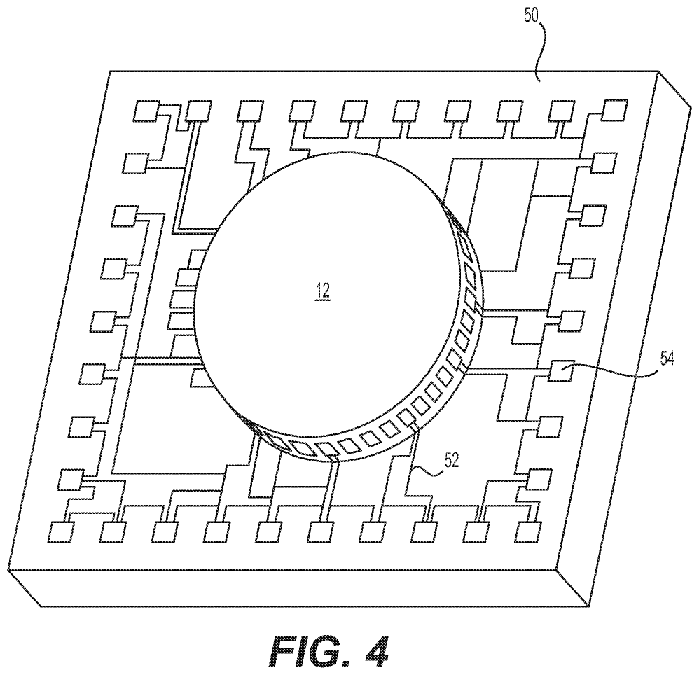

Cylindrical ICs of embodiments of the invention may be packaged in conventional dual in-line package (DIP) or surface-mount (SMT) packages so that the cylindrical ICs may be mounted on conventional PCBs to fabricate circuits connected with conventional planar ICs. Although it does not show the DIP package, FIG. 4 illustrates a cylindrical IC 12 mounted on a substrate 50 and connected via leads 52 to terminals 54 which provide connectivity to other devices and circuitry.

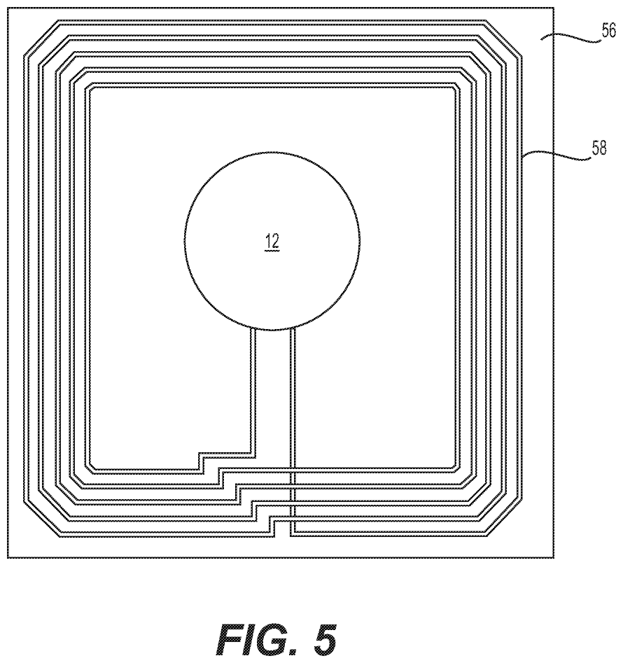

Cylindrical ICs of embodiments of the invention may be integrated with an antenna or sensors in the horizontal or vertical wiring planes to make radio frequency identification (RFID) transmission and detection systems with passive or active low cost memory tags. Such RFID tags can be fabricated using roll-to-roll technology at a low cost, allowing large volume implementation of inventory management systems, internet of things (IoT), or other big database generation applications. FIG. 5 illustrates a cylindrical IC 12 mounted on a substrate 56 and connected to an antenna 58 to form a low cost RFID tag.

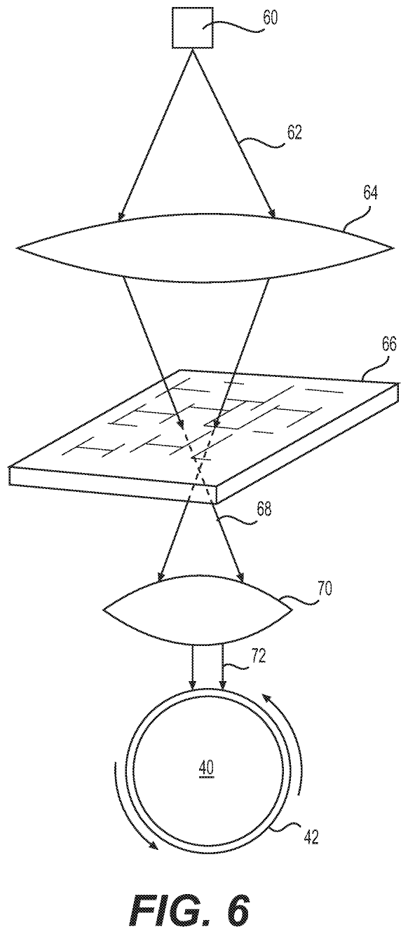

In alternative embodiments of the invention, conventional photolithography techniques such as step-and-repeat refractive optics or scanning projection reflecting optics or other methods presently being used for planar wafer pattern printing can be used to print on the sidewalls of the rotating silicon cylinder. FIG. 6 illustrates an optical photolithography camera using a planar photomask and refractive lens step-and-repeat optics to print the circuit pattern on the curved side of the silicon cylinder, in accordance with embodiments of the invention. A light source 60 projects light 62 through a condenser lens 64. Light 68 from the condenser lens 64 passes through a planar photomask 66 to a reduction lens 70. Light 72 from the reduction lens strikes photoresist 42 on a rotating silicon cylinder 40 to form a strip field of focus. The sequential rotation and stepping of the silicon cylinder 40 enables the scanned circuitry pattern from the planar photomask 66 to be printed along the entire sidewall.

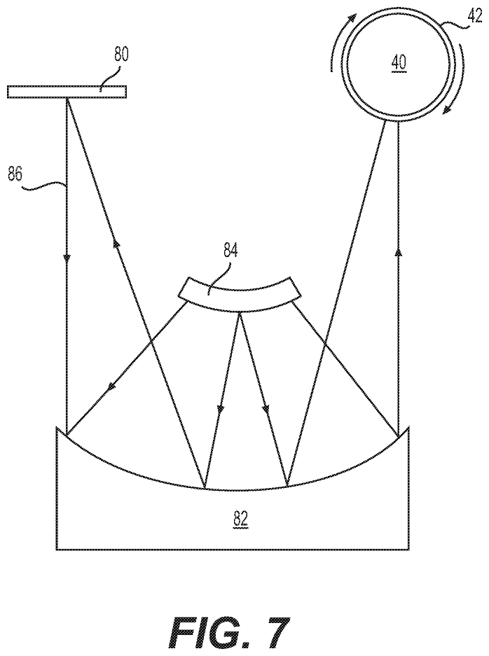

In an alternative embodiment to print on the curved sides of a cylinder using a planar photomask, FIG. 7 illustrates an optical photolithography camera using a planar photomask and reflective optics to print the circuit pattern on the curved side of the silicon cylinder. A strip field from the photomask will be in focus on the curved surface of the silicon cylinder after it passes through the reflective mirror optics. Subsequently, the photomask strip is scanned over the next field of focus on the planar photomask as the cylinder is rotated a radians, enabling the complete printing of the chip pattern. Both FIG. 6 and FIG. 7 illustrate the ability to print patterns on the sidewall of a cylinder using conventional photolithography methods (i.e., without the novel concentric photolithography camera and curved photomask illustrated in FIG. 3. Another alternative embodiment would be to use direct writing electron beam lithography without the need for photomasks.

Systems and methods of concentric photolithography of embodiments of the invention enable the complete fabrication process to be fully automated to operate on a continuous basis with minimal clean room contamination requirements, substantially reducing the fab clean room building size and volume and the associated construction and operating costs.

Cylindrical ICs of embodiments of the invention may be integrated in three dimensions with other devices or circuits using radial wiring schemes on laminate dielectric surfaces in perpendicular planes. Such three-dimensional integration of the cylindrical IC allows cooling of the electronics by efficient conduction, convention, and radiation heat transfer.

The cylindrical geometry would enable improved computer architecture by enabling effective logic and memory interface, faster systems, and effective telecommunication devices.

Neural network circuits may be fabricated utilizing the cylindrical ICs of embodiments of the invention with neural wiring and logic elements in the vertical plane radially emanating from one node to another to form neuromorphic systems.

Supercomputers designed with cylindrical ICs of embodiments of the invention would be capable of very high performance due to vertical logic and memory integration, efficient power distribution, and effective thermal management.

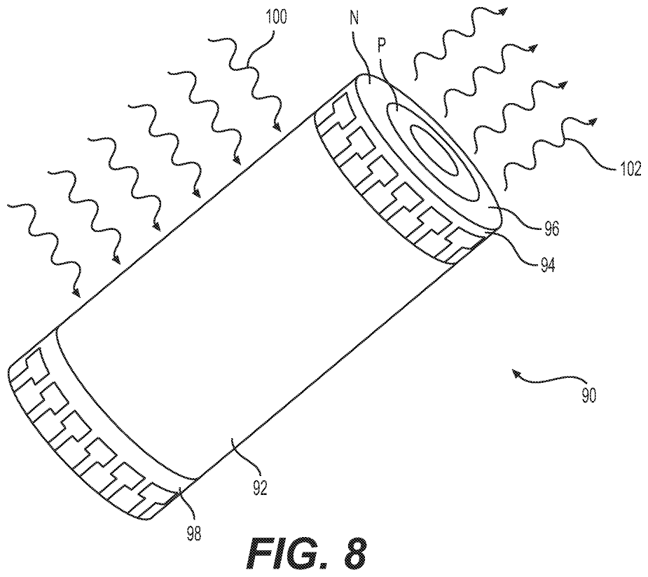

Light emitting diodes (LEDs) may be fabricated by epitaxially depositing thin p-type and n-type compound semiconductor thin films on the side walls of a lattice matched semiconductor as shown in FIG. 8. LED device 90 comprises a cylindrical solar cell 92 (which converts incident light 100 into electrical energy) and a cylindrical IC 94 at one end (a second cylindrical IC 98 may optionally be placed at the opposing end). By applying an electrical potential, the p-n diode 96 formed will generate and emit photons 102 due to the interaction of the electrons with the holes, as in a conventional LEDs. The cylindrical geometry will enable high lighting efficiency, lower cost and integration with electronic circuitry fabricated on the side wall. Similarly, photovoltaic solar cells and photodetectors may be constructed to convert light impinging on the side wall or end of the p-n diode to generate electrical power. Opto-electronic systems may be designed by bringing the optical fiber signals directly to the cylindrical ICs of embodiments of the invention in the vertical geometric scheme.

Microwave and ultrasonic piezoelectric sources and detectors may also be constructed in the cylindrical geometry shown in FIG. 8 enabling higher power density, lower cost, and integration with logic and memory circuitry.

Systems on a chip (SoC) may be fabricated with three-dimensionally integrated cylindrical ICs of embodiments of the invention with high speed performance and extensive power distribution and thermal management capabilities.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

That which is claimed:

1. An integrated circuit comprising:
a silicon cylinder having a sidewall, wherein a plurality of semiconductor devices have been printed on the sidewall;
one or more electrical leads electrically connected to each semiconductor device; and
a plurality of radial wiring interconnects projecting outward from the sidewall.

2. The integrated circuit of claim 1, wherein at least some of the electrical leads terminate at a bottom edge of the sidewall.

3. The integrated circuit of claim 1, wherein one or more of the electrical leads terminate at a corresponding one of the radial wiring interconnects, enabling three dimensional integration.

4. A method of manufacturing an integrated circuit, the method comprising:
printing a plurality of semiconductor devices on a sidewall of a silicon cylinder; and
slicing the silicon cylinder into a plurality of thinner silicon cylinders, each thinner silicon cylinder having a plurality of semiconductor devices printed on its sidewall.

5. The method of claim 4, wherein printing a plurality of semiconductor devices on a sidewall of a silicon cylinder comprises:
placing a concentric photomask in a position surrounding at least a portion of the silicon cylinder; and
projecting light from outside the concentric photomask radially inward toward the silicon cylinder.

6. The method of claim 4, wherein printing a plurality of semiconductor devices on a sidewall of a silicon cylinder comprises:
projecting light through a planar photomask toward the silicon cylinder; and
rotating the silicon cylinder to enable the light to sequentially strike different portions of the silicon cylinder.
